(19) United States
(12) Patent Application Publication
(10) Pub. No.: US 2007/0139129 A1
(43) Pub. Date: Jun. 21, 2007

(54) RF balanced matching device

(75) Inventor: Yun Hwi Park, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/600,063

(22) Filed: Nov. 16, 2006

(30) Foreign Application Priority Data
Dec. 19, 2005 (KR) 10-2005-0125541

(51) Int. Cl. H03K 3/02

(52) U.S. Cl. 331/152

(57) ABSTRACT

In an RF balanced matching device, a first capacity pattern of a first area is formed on a first ceramic sheet. A second capacity pattern of a second area is formed on the first ceramic sheet, spaced apart from the first capacity pattern at a predetermined distance. A third capacity pattern of a third area is formed on a second ceramic sheet stacked on the first ceramic sheet, overlapping perpendicular to the first capacity pattern. The third capacity pattern cooperates with the first capacity pattern to form a first capacitance. Also, a fourth capacity pattern of a fourth area is formed on the second ceramic sheet, overlapping perpendicular to the second capacity pattern. The fourth capacity pattern cooperates with the second capacity pattern to form a second capacitance. An inductance pattern has a predetermined electrical length and connects the third capacity pattern with the fourth capacity pattern.

### CLAIM OF PRIORITY

This application claims the benefit of Korean Patent Application No. 2005-125541 filed on Dec. 19, 2005 in the Korean Intellectual Property Office, the disclosure of which is incorporated herein by reference.

### BACKGROUND OF THE INVENTION

1. Field of the Invention

The present invention relates to a Radio Frequency (RF) balanced matching device applicable to an RF circuit. More particularly, the present invention relates to an RF balanced matching device in which two signal lines of a balanced circuit are formed in a simple, physically and electrically symmetric configuration on a Low Temperature Cofired Ceramics (LTCC) substrate, thereby enhancing impedance match in the balanced circuit, creating less parasitic components and thus preventing degradation in properties.

2. Description of the Related Art

In general, efforts are under way to reduce noise properties of RF integrated circuits (IC) in low-noise amplifiers (LAN), mixers, oscillator (VCO) and the like. For this purpose, a conventional single ended (unbalanced) structure is rapidly making way for a balanced (differential) structure. Here, signals between the unbalanced structure such as antennas and filters and the balanced structure such as the low-noise amplifiers (LNA) should be connected, thereby necessitating a Balun transformer therebetween.

However, impedance mismatch still exists between the Balun transformer and the balanced LNA. Thus impedance match, as shown in FIG. 1 should be achieved via a matching device constructed of an inductor L and a capacitor.

FIG. 1 is a circuit diagram illustrating an RF balanced matching device connected between a filter and a low-noise amplifier according to the prior art.

Referring to FIG. 1, the RF balanced matching device 20 is connected between the filter (SAW) 10 and the low-noise amplifier (LNA) 30. The RF balanced matching device 20 matches impedance between the filter 10 and the low-noise amplifier 30. A signal S1 inputted to the filter 10 is outputted to the low-noise amplifier 30 without any loss.

The RF balanced matching device is formed on a Low Temperature Co-fired Ceramics (LTCC) substrate. With this LTCC technology, a plurality of thin layers are connected through a via hole to form a three-dimensional inductor and a capacitor on the substrate. The LTCC technology has been predominantly adopted in the RF module recently.

The RF passive device such as filters and Baluns has been embedded in the LTCC-based apparatus but matching circuits of the inductor and capacitor have been seldom embedded therein for the following reasons. First, device values are hard to predict due to parasitic components and second, matching circuits of the balanced structure are hardly in a symmetrical configuration.

FIG. 2 is a cross-sectional view illustrating a conventional RF balanced matching device.

The conventional RF balanced matching device of FIG. 2 is formed on a LTCC multilayer structure. The RF balanced matching device includes a first transmission pattern TP1, a first capacity pattern CP1, a second transmission pattern TP2, a second capacity pattern CP2 and an inductor pattern LP. The first pattern TP1 is connected to a terminal T2+. The first capacity pattern CP1 forms a capacitance between the first transmission pattern TP1 and a terminal T1+. The second transmission pattern PT2 is connected to a terminal T2−. Also, a second capacitor pattern CP2 forms a capacitance between the second transmission pattern TP2 and a terminal T1−. The inductor pattern LP connects the terminal T2+ with the second capacity pattern CP2.

But the conventional RF balanced matching device needs to employ the first transmission pattern TP1 to connect the terminal T1+ with the terminal T2+, even though not contributive to impedance matching. Likewise, the transmission pattern TP2 is necessarily adopted to connect the terminal T1− with the terminal T2−. These first and second transmission patterns TP1 and TP2 disadvantageously cause parasitic components and also parasitic capacitance between the first and second capacity patterns CP1 and CP2 and a ground.

Moreover, the inductor pattern LP is not symmetrical with respect to the terminals T2+ and T2−, thereby failing to attain precise impedance matching.

### SUMMARY OF THE INVENTION

The present invention has been made to solve the foregoing problems of the prior art and it is therefore an object according to certain embodiments of the present invention is to provide an RF balanced matching device in which two signal lines of a balanced circuit are formed in a simple, physically and electrically symmetric configuration on a Low Temperature Cofired Ceramics (LTCC) substrate, thereby enhancing impedance match of the balanced circuit, creating less parasitic components and thus preventing degradation in properties.

According to an aspect of the invention for realizing the object, there is provided a radio frequency balanced matching device including a first capacity pattern of a first area formed on a first ceramic sheet; a second capacity pattern of a second area formed on the first ceramic sheet, the second capacity pattern spaced apart from the first capacity pattern at a predetermined distance; a third capacity pattern of a third area formed on a second ceramic sheet stacked on the first ceramic sheet, overlapping perpendicular to the first capacity pattern, the third capacity pattern cooperating with the first capacity pattern to form a first capacitance; a fourth capacity pattern of a fourth area formed on the second ceramic sheet, overlapping perpendicular to the second capacity pattern, the fourth capacity pattern cooperating with the second capacity pattern to form a second capacitance; and an inductance pattern having a predetermined electrical length and connecting the third capacity pattern with the fourth capacity pattern.

The first capacitance is equal to the second capacitance.

The first area of the first capacity pattern is equal to the second area of the second capacity pattern. The first capacity pattern is symmetrical laterally with respect to the second capacity pattern.

The first capacity pattern is symmetrical vertically with respect to the third capacity pattern. The first capacity pattern is symmetrical vertically with respect to the third capacity pattern.

The fourth area of the fourth capacity pattern is equal to the third area of the third capacity pattern. The fourth capacity pattern is symmetrical laterally with respect to the third capacity pattern.

The fourth area of the fourth capacity pattern is equal to the second area of the second capacity pattern. The second capacity pattern is symmetrical vertically with respect to the second capacity pattern.

The inductance pattern includes a first pattern formed on the second ceramic sheet and connected to the third capacity pattern; a second pattern formed on the second ceramic sheet and connected to the fourth capacity pattern; and a third pattern formed on at least one of other ceramic sheets adjacent to the second ceramic sheet, the third pattern connecting the first pattern with the second pattern through a via hole.

The radio frequency balanced matching device further includes a ground pattern formed on upper and lower ceramic sheets to form a stack structure together with the first and second ceramic sheets.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram illustrating an RF balanced matching device connected between a filter and a low-noise amplifier according to the prior art;

FIG. 2 is a cross-sectional configuration view illustrating an RF balanced matching device according to the prior art;

FIG. 3 is a perspective view illustrating configuration of an RF balanced matching device according to the invention;

FIG. 4 is a cross-sectional view illustrating the RF balanced matching device cut along the line A-A in FIG. 3; and

FIG. 5 is a circuit diagram illustrating an RF balanced matching device according to the invention.

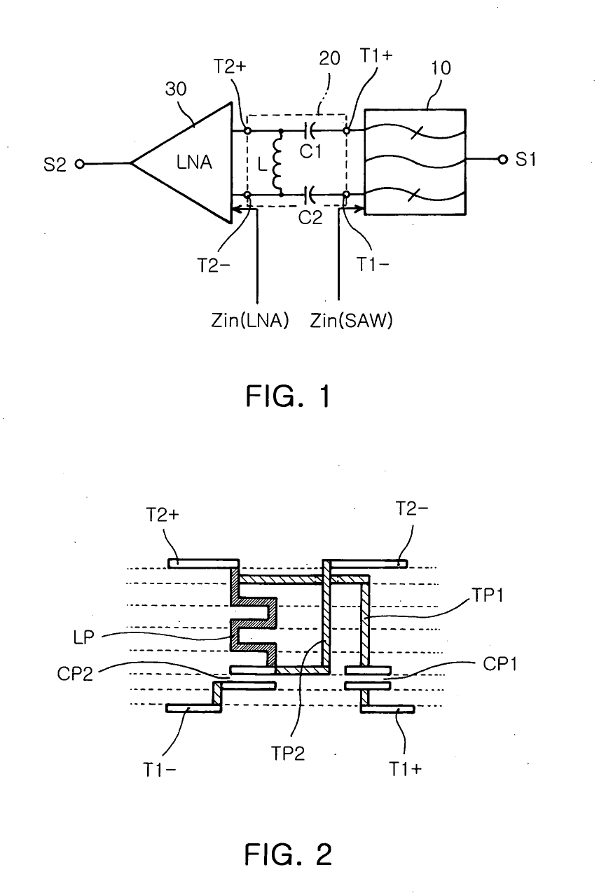

### DETAILED DESCRIPTION OF THE PREFERRED EMBODIMENT

Preferred embodiments of the present invention will now be described in detail with reference to the accompanying drawings, in which the same reference numerals are used throughout the different drawings to designate the same or similar components.

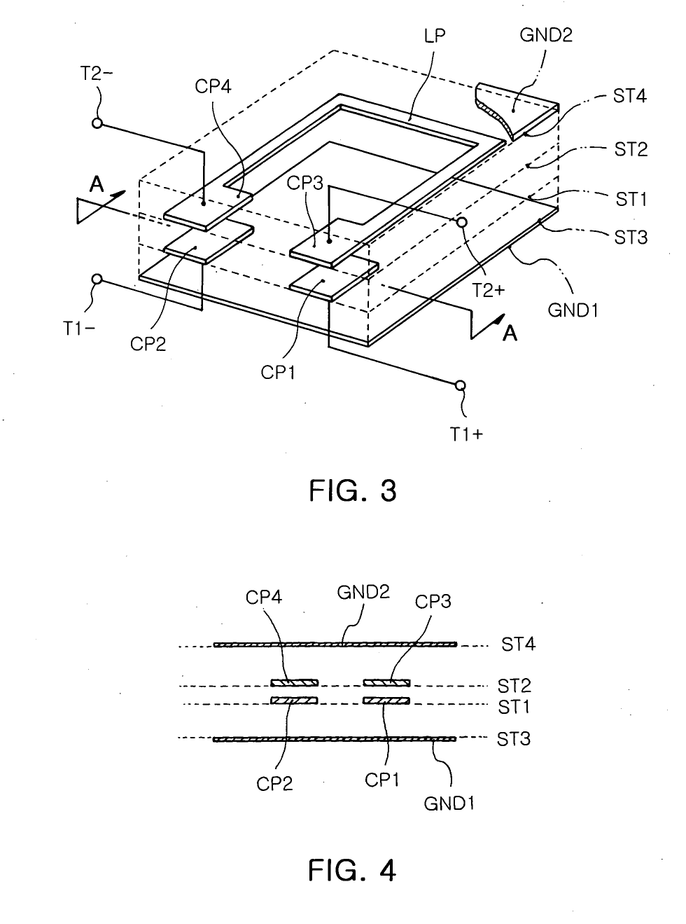

FIG. 3 is a configuration view illustrating an RF balanced matching device according to the invention and FIG. 4 is a cross-sectional view illustrating the RF balanced matching device cut along the line A-A in FIG. 3.

Referring to FIGS. 3 and 4, the RF balanced matching device of the invention is disposed on a Low Temperature Cofired Ceramics (LTCC) substrate where a plurality of ceramic sheets are stacked. The LTCC substrate shown in FIG. 3 has first to fourth ceramic sheets ST1 to ST4 stacked therein.

First, the first ceramic sheet ST1 has a first capacity pattern CP1 of a first area and a second capacity pattern CP2 of a second area formed thereon. Here, the second capacity pattern CP2 is spaced apart from the first capacity pattern CP1.

Then, the second ceramic sheet ST2 stacked on the first ceramic sheet ST1 has third and fourth capacity patterns CP3 and CP4 and an inductance pattern LP formed thereon.

The third capacity pattern CP3 of a third area is formed on a second ceramic sheet, overlapping perpendicular to the first capacity pattern CP1. The third capacity pattern CP3 cooperates with the first capacity pattern CP1 to form a first capacitance C10. Likewise, the fourth capacity pattern CP4 of a fourth area is formed on the second ceramic sheet, overlapping perpendicular to the second capacity pattern CP2. The fourth capacity pattern CP4 cooperates with the second capacity pattern CP2 to form a second capacitance C20.

The inductance pattern LP has a predetermined electrical length and connects the third capacity pattern CP3 with the fourth capacity pattern CP4.

In this RF balanced matching device of the invention, to ensure precise impedance matching, two signal lines between a terminal T1+ and a terminal T1− and also between a terminal T2+ and a terminal T2− should be symmetrical to each other, i.e., in terms of electrical and physical configuration.

When it comes to electrical symmetrical configuration, in the RF balanced matching device of the invention, preferably the first capacitance C10 formed by the first and third capacity patterns CP1 and CP3 is equal to the second capacitance C20 formed by the second and fourth capacity patterns CP2 and CP4.

Then physical symmetrical configuration will be explained.

First, in the RF balanced matching device of the invention, the first capacity pattern CP1 should be symmetrical with respect to the second capacity pattern CP2, thereby enabling more precise impedance matching between the two terminals. To achieve more precise impedance matching, the first and second capacity patterns CP1 and CP2 are necessarily of the same size and configuration, which will be given in greater detail hereunder.

The first area of the first capacity pattern CP1 is equal to the second area of the second capacity pattern CP2. Preferably, the first capacity pattern CP1 is symmetrical laterally with respect to the second capacity pattern CP2. Also, the first area of the first capacity pattern CP1 is equal to the third area of the third capacity pattern CP3. The first capacity pattern CP1 is symmetrical vertically with respect to the third capacity pattern CP2.

Second, in the RF balanced matching device of the invention, the third capacity pattern CP3 and the fourth capacity pattern CP4 are symmetrical to each other, thereby matching impedance more accurately between both terminals. To ensure accurate impedance matching as just described, the third and fourth capacity patterns CP3 and CP4 should be equally sized and configured, which will be explained in greater detail hereunder.

The fourth area of the fourth capacity pattern CP4 is equal to the third area of the third capacity pattern CP3. The fourth capacity pattern CP4 is symmetrical laterally with respect to the third capacity pattern CP3. Likewise, the fourth area of the fourth capacity pattern CP4 is equal to the second area of the second capacity pattern CP2. The fourth capacity pattern CP4 is symmetrical vertically with respect to the second capacity pattern CP2.

Meanwhile, the inductance pattern LP, as shown in FIG. 3, is disposed on the second ceramic sheet ST2 in parallel with an edge thereof.

Moreover, the RF balanced matching device of the invention further includes ground patterns GND1 and GND2. The ground pattern GND1 is formed on the third ceramic sheet ST3, and the ground pattern GND2 is formed on the fourth ceramic sheet ST4. Here, the third ceramic sheet ST3 is stacked underneath the first ceramic sheet ST1 and the fourth ceramic sheet ST4 is stacked on the second ceramic sheet ST2.

As described above, in the RF balanced matching device of the invention, a structure from the terminal T1+ is symmetrical with respect to a structure from the terminal T1−, thereby allowing both terminals to be out of phase with each other. Likewise, a structure from the terminal T2+ is symmetrical with respect to a structure from the terminal T2−, thereby allowing both terminals to be out of phase with each other.

Such a symmetrical configuration ensures more precise impedance matching for the RF balanced matching device of the invention.

The inductance pattern LP as just described may be disposed on the second ceramic sheet ST2 in parallel with an edge thereof. Alternatively, one portion of the inductance pattern LP may be formed on the second ceramic sheet ST2 and another portion may be formed on a ceramic sheet adjacent to the second ceramic sheet ST2, e.g., on the first ceramic sheet ST1 or a fifth ceramic sheet interleaved between the second ceramic sheet ST2 and the fourth ceramic sheet ST4. Here, the one portion of the inductance pattern LP may be connected to the other portion thereof.

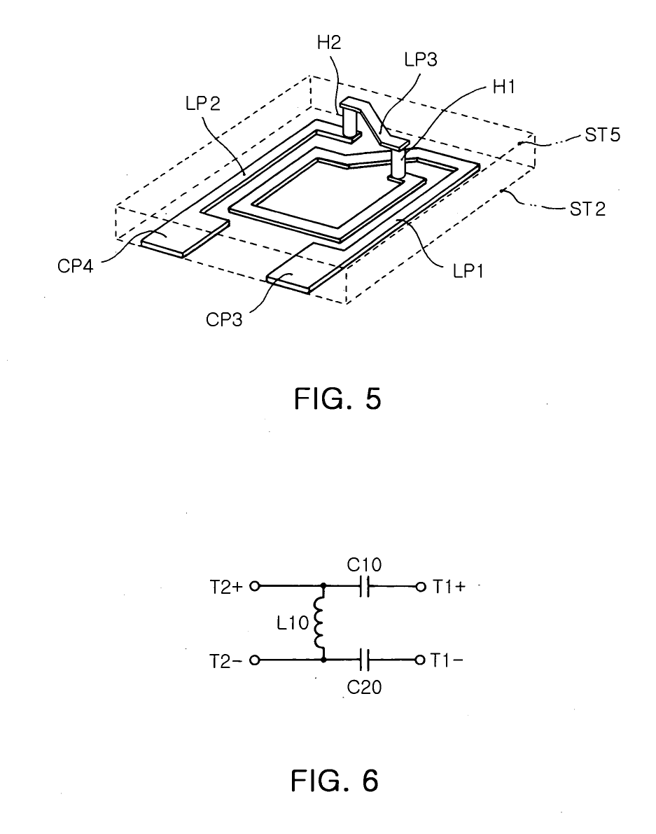

An example of this structure will be explained hereunder with reference to FIG. 5.

FIG. 5 is a modified example of the inductance pattern shown in FIG. 3.

Referring to FIG. 5, the inductance patterns LP include a first pattern LP1, a second pattern LP2 and a third pattern LP3. The first pattern LP1 is formed on a second ceramic sheet ST2 and connected to a third capacity pattern CP3. The second pattern LP2 is formed on the second ceramic sheet ST2 and connected to a fourth capacity pattern CP4. Also, the third pattern LP3 is formed on at least one of other ceramic sheets adjacent to the second ceramic sheet ST2, and connects the first pattern LP1 with the second pattern LP2 through via holes H1 and H2.

Here, the at least one of other ceramic sheets designates a ceramic sheet other than the second ceramic sheet ST2. For example, as shown in FIG. 5, the other ceramic sheet may be a fifth ceramic sheet ST5 stacked between the second ceramic sheet ST3 and the fourth ceramic sheet ST. Alternatively, the other ceramic sheet may be the first ceramic sheet ST1, the third ceramic sheet ST3 or the fourth ceramic sheet ST4.

FIG. 6 is a circuit diagram illustrating an RF balanced matching device according to the invention.

Referring to FIG. 6, in the RF balanced matching device of the invention, C1 denotes a first capacitance formed by the first and third capacity patterns CP1 and CP3. C20 denotes a second capacitance C20 formed by the second and fourth capacity patterns CP2 and CP4. L10 is an inductance formed by the inductance patterns LP.

The RF balanced matching device of the invention as described above does not require an additional pattern other than the capacity pattern and inductance pattern. This suppresses parasitic components, which however is not realized by a conventional RF balanced matching device.

As set forth above, according to preferred embodiments of the invention, in an RF balanced matching device applicable to an RF circuit, two signal lines of a balanced circuit are formed in a simple, physically and electrically symmetrical configuration on an LTCC substrate, thereby enhancing impedance match of the balanced circuit, creating less parasitic components and thus preventing degradation in properties.

That is, the RF balanced matching device of the invention does not create parasitic components resulting from additional via holes and lines between inductors and capacitors and also between devices and terminals, which have troubled the conventional RF balanced matching device. In addition, the invention allows + and − terminals to be symmetrical to each other more precisely, thereby preventing deterioration in properties. Moreover, the invention is simplified in its structure. This renders a balanced impedance more easily predictable and thus significantly reduces time necessary for designing an internal matching device.

While the present invention has been shown and described in connection with the preferred embodiments, it will be apparent to those skilled in the art that modifications and variations can be made without departing from the spirit and scope of the invention as defined by the appended claims.

What is claimed is:

1. A radio frequency balanced matching device comprising:
a first capacity pattern of a first area formed on a first ceramic sheet;
a second capacity pattern of a second area formed on the first ceramic sheet, the second capacity pattern spaced apart from the first capacity pattern at a predetermined distance;
a third capacity pattern of a third area formed on a second ceramic sheet stacked on the first ceramic sheet, overlapping perpendicular to the first capacity pattern, the third capacity pattern cooperating with the first capacity pattern to form a first capacitance;
a fourth capacity pattern of a fourth area formed on the second ceramic sheet, overlapping perpendicular to the second capacity pattern, the fourth capacity pattern cooperating with the second capacity pattern to form a second capacitance; and
an inductance pattern having a predetermined electrical length and connecting the third capacity pattern with the fourth capacity pattern.

2. The radio frequency balanced matching device according to claim 1, wherein the first capacitance is equal to the second capacitance.

3. The radio frequency balanced matching device according to claim 2, wherein the first area of the first capacity pattern is equal to the second area of the second capacity pattern.

4. The radio frequency balanced matching device according to claim 3, wherein the first capacity pattern is symmetrical laterally with respect to the second capacity pattern.

5. The radio frequency balanced matching device according to claim 3, wherein the first area of the first capacity pattern is equal to the third area of the third capacity pattern.

6. The radio frequency balanced matching device according to claim 4, wherein the first area of the first capacity pattern is equal to the third area of the third capacity pattern.

7. The radio frequency balanced matching device according to claim 6, wherein the first capacity pattern is symmetrical vertically with respect to the third capacity pattern.

8. The radio frequency balanced matching device according to claim 5, wherein the first capacity pattern is symmetrical vertically with respect to the third capacity pattern.

9. The radio frequency balanced matching device according to claim 2, wherein the fourth area of the fourth capacity pattern is equal to the third area of the third capacity pattern.

10. The radio frequency balanced matching device according to claim 7, wherein the fourth capacity pattern is symmetrical laterally with respect to the third capacity pattern.

11. The radio frequency balanced matching device according to claim 9, wherein the fourth area of the fourth capacity pattern is equal to the second area of the second capacity pattern.

12. The radio frequency balanced matching device according to claim 10, wherein the fourth area of the fourth capacity pattern is equal to the second area of the second capacity pattern.

13. The radio frequency balanced matching device according to claim 12, wherein the second capacity pattern is symmetrical vertically with respect to the second capacity pattern.

14. The radio frequency balanced matching device according to claim 11, wherein the second capacity pattern is symmetrical vertically with respect to the second capacity pattern.

15. The radio frequency balanced matching device according to claim 2, wherein the inductance pattern is disposed on the second ceramic sheet in parallel with an edge thereof.

16. The radio frequency balanced matching device according to claim 2, wherein the inductance pattern comprises:
a first pattern formed on the second ceramic sheet and connected to the third capacity pattern;
a second pattern formed on the second ceramic sheet and connected to the fourth capacity pattern; and
a third pattern formed on at least one of other ceramic sheets adjacent to the second ceramic sheet, the third pattern connecting the first pattern with the second pattern through a via hole.

17. The radio frequency balanced matching device according to claim 2, further comprising: a ground pattern formed on upper and lower ceramic sheets to form a stack structure together with the first and second ceramic sheets.
